(19) United States
(12) Patent Application Publication
(10) Pub. No.: US 2013/0341591 A1
(43) Pub. Date: Dec. 26, 2013

(54) LIGHT EMITTING DIODE STRUCTURE AND MANUFACTURING METHOD THEREOF

(71) Applicant: LEXTAR ELECTRONICS CORPORATION, Hsinchu (TW)

(72) Inventor: Ming-Sheng Chen, Changhua County (TW)

(73) Assignee: Lextar Electronics Corporation, Hsinchu (TW)

(21) Appl. No.: 13/870,207

(22) Filed: Apr. 25, 2013

(30) Foreign Application Priority Data
Jun. 21, 2012 (TW) 101122256

(51) Int. Cl. H01L 33/58; H01L 33/04

(52) U.S. Cl. CPC H01L 33/58; H01L 33/04
USPC 257/13; 438/29

(57) ABSTRACT

The present invention relates to a light emitting diode (LED) structure and a manufacturing method thereof. A first semiconductor stacking layer consisting of a first type semiconductor layer, a light-emitting layer, a second type semiconductor layer and a second type light-guiding layer is sequentially formed on a semiconductor substrate. Partial of the first type semiconductor layer, the light-emitting layer, the second type semiconductor layer and the second type light-guiding layer is removed. A second semiconductor stacking layer consisting of the first type semiconductor layer, the light-emitting layer, the second type semiconductor layer and the second type light-guiding layer is defined in a light-emitting area. A transparent conductive layer is formed on a surface of the second type light-guiding layer of the second semiconductor stacking layer.

This application claims the benefit of Taiwan application Serial No. 101122256, filed Jun. 21, 2012, the subject matter of which is incorporated herein by reference.

### BACKGROUND OF THE INVENTION

1. Field of the Invention

The invention relates in general to a light emitting diode (LED) structure and a manufacturing method thereof, in which a stacking layer is formed, and the refractive index of each layer of the stacking layers is matched with each other, so that the total reflection inside the structure is reduced, and the luminous efficiency is increased.

2. Description of the Related Art

Light emitting diode (LED) relates to a solid light-emitting element made from a semiconductor material. LED, having the features of small volume, low temperature of heating generation, high lamination, low power consumption, long lifespan and being suitable for mass production, has been widely used as a lighting source for various lighting devices or back light modules. As the application of LED is getting more and more popular, how to increase the luminous efficiency of the LED or increase the brightness and uniformity of the output light of the LED has become a prominent task and a development goal to the industries. Through the change in design of the LED structure, the luminous efficiency, brightness and uniformity of the LED can be effectively and significantly improved.

According to the current technology of LED structure, a light-emitting layer or an active layer is disposed at the PN junction between the p-type semiconductor and the n-type semiconductor. The light-emitting layer or the active layer can be realized by a multi-quantum well (MQW) structure layer. When a voltage is applied between the positive polarity (or p-type) and the negative polarity (or n-type) of the LED structure so that a current flows and makes the PN junction between the p-type semiconductor and the n-type semiconductor illuminate, the material characteristics of the light-emitting layer or the active layer increase the luminous efficiency when the current flows through.

Besides, according to the current technology, indium tin oxide (ITO) having the feature of transparency, can be used as a conductivity and current spreading layer and can be disposed on the p-type semiconductor. However, the light generated by the light-emitting layer or the active layer can be emitted from various angles inside the structure. When the light is emitted to the outside (such as the air outside the current spreading layer or the surface of the structure), the light will be refracted due to the variation in the refractive index of the interface and the angle of incidence. Even total reflection may be occurred and the generated light is reflected back to the structure to affect the luminous efficiency.

More detail description, a structural design of LED with transparent conductive layer disclosed in Taiwan Patent No. 1258226 “LED with Transparent Conductive Layer” is an example of increasing luminous brightness by reducing total reflection of the light. Referring to FIG. 1, a structural diagram of a conventional gallium nitride light-emitting element is shown. As illustrated in FIG. 1, the gallium nitride light-emitting element 100 mainly includes a substrate 102, an n-type gallium nitride semiconductor layer 104, an active layer 106, a p-type gallium nitride semiconductor layer 108, a high refractive index contact layer 109, a transparent conductive layer 110, an anode electrode 112 and a cathode electrode 114. The stacking of elements is illustrated in the diagram.

As described above, the high refractive index contact layer 109 is a transparent conductive material whose refractive index is larger than 2.0. Examples of the transparent conductive materials include indium-cerium oxide (ICO) and indium zinc oxide (IZO). The refractive index of the high refractive index contact layer 109 is smaller than the refractive index (between 2.4 to 2.5) of the p-type gallium nitride semiconductor layer stacked underneath but is larger than the refractive index (1.8) of the ITO transparent conductive layer 110 stacked atop. That is, the refractive index of the high refractive index contact layer 109 is between that of the transparent conductive layer 110 and that of the p-type gallium nitride semiconductor layer 108. By such design, the total reflection inside the structure is effectively reduced, and the light generated inside the structure is guided to emit to the outside of the structure.

Although the change in design of the LED structure improves the luminous efficiency of overall elements, the scope of the high refractive index contact layer 109 only corresponds to the transparent conductive layer 110. Hence, it may affect the current spreading effect and the luminous efficiency. The choice of the material of the high refractive index contact layer 109 will affect the formation in the manufacturing process and characteristics of the gallium nitride semiconductor layer 108 disposed under the high refractive index contact layer 109, the time and cost of the manufacturing process may be increased accordingly.

### SUMMARY OF THE INVENTION

The invention is directed to a light emitting diode (LED) structure and a manufacturing method thereof, in which a stacking layer is formed by epitaxial growth and refractive index of each stacking layer is matched with each other so that the total reflection inside the structure can be reduced, the luminous efficiency can be increased, and the time and cost required in the manufacturing process can be reduced.

According to one embodiment of the present invention, an LED structure is provided. The LED structure includes a semiconductor substrate, a first type semiconductor layer, a light-emitting layer, a second type semiconductor layer, a second type light-guiding layer, and a transparent conductive layer. The first type semiconductor layer is formed on the semiconductor substrate. The light-emitting layer is formed on partial surface of the first type semiconductor layer. The second type semiconductor layer corresponds to a top surface of the light-emitting layer and is formed on the light-emitting layer. The second type light-guiding layer corresponds to a top surface of the second type semiconductor layer and is formed on the second type semiconductor layer. The second type light-guiding layer and the second type semiconductor layer have the same polarity. The transparent conductive layer corresponds to the top surface of the second type light-guiding layer and is formed on the second type light-guiding layer. The refractive index of the second type light-guiding layer is between the refractive indexes of the transparent conductive layer and the second type semiconductor layer.

According to another embodiment of the present invention, a manufacturing method of an LED structure is provided. The method includes the following steps. A semiconductor substrate is provided. A first semiconductor stacking layer is formed on the semiconductor substrate. The first semiconductor stacking layer consists of a first type semiconductor layer, a light-emitting layer, a second type semiconductor layer and a second type light-guiding layer formed in sequence. The first semiconductor stacking layer is patterned to remove partial of the first type semiconductor layer, the light-emitting layer, the second type semiconductor layer and the second type light-guiding layer. A second semiconductor stacking layer consisting of the first type semiconductor layer, the light-emitting layer, the (second type semiconductor layer and the second type light-guiding layer is defined in a light-emitting area, and an exposed surface of the first type semiconductor layer is remained in a non-light-emitting area. A transparent conductive layer is formed on a surface of the second type light-guiding layer of the second semiconductor stacking layer. The refractive index of the second type light-guiding layer is between the refractive indexes of the second type semiconductor layer and the transparent conductive layer.

According to the above conception, wherein the second type light-guiding layer is realized by a p-type aluminum indium gallium nitride (AlInGaN), and the second type light-guiding layer is formed by the epitaxial process.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a structural diagram of a conventional gallium nitride light-emitting element; and

FIGS. 2 (a) to (d) are procedures of a manufacturing method of an LED structure according to an exemplary embodiment of the present invention.

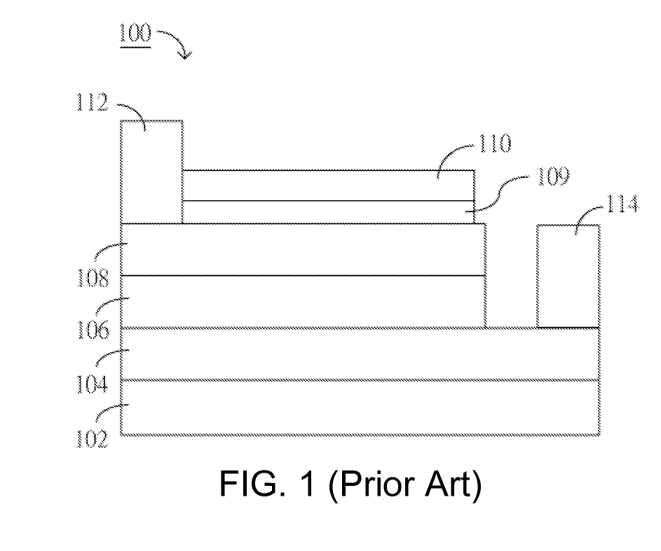

### DETAILED DESCRIPTION OF THE INVENTION

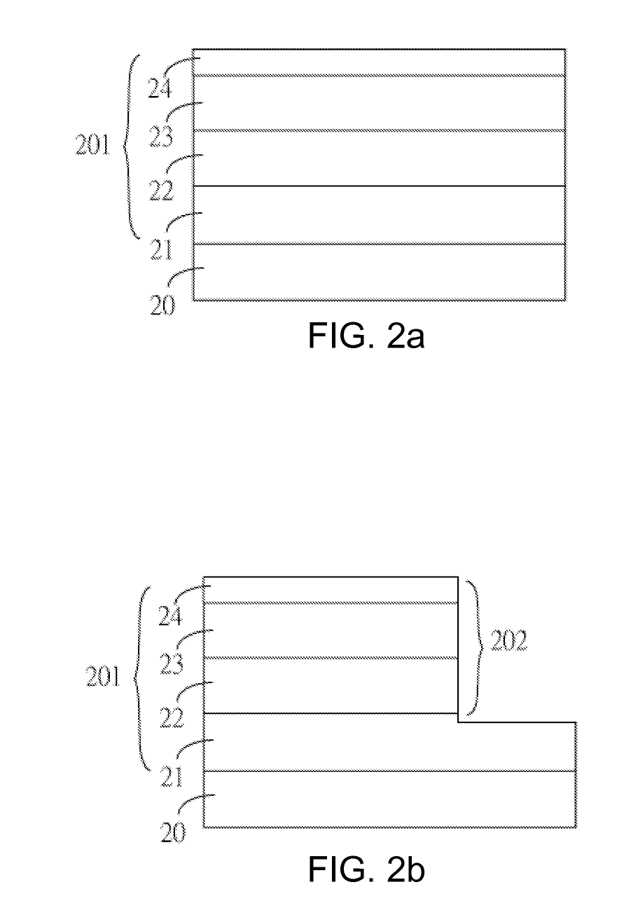

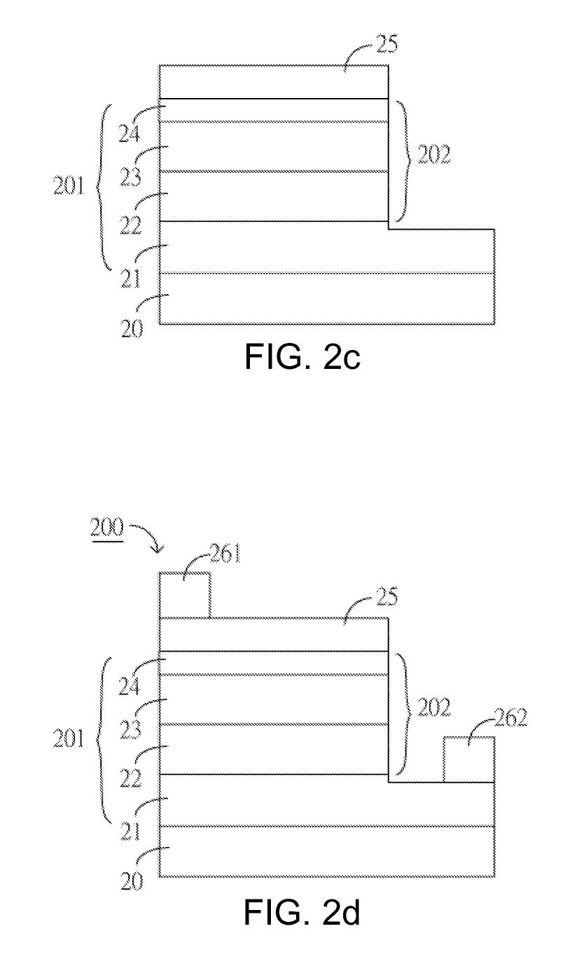

The present invention is exemplified by an exemplary embodiment disclosed below. Referring to FIGS. 2 (a) to (d), procedures of a manufacturing method of an LED structure according to an exemplary embodiment of the present invention are shown. Referring to FIG. 2 (a). Firstly, a semiconductor substrate 20 is provided, and a first type semiconductor layer 21, a light-emitting layer 22, a second type semiconductor layer 23 and a second type light-guiding layer 24 are sequentially formed on the semiconductor substrate 20. The first type semiconductor layer 21, the light-emitting layer 22, the second type semiconductor layer 23 and the second type light-guiding layer 24 are stacked to each other to form a first semiconductor stacking layer 201.

In the present embodiment, the first type semiconductor layer 21 is realized by an n-type gallium nitride (GaN) structure, the second type semiconductor layer 23 is realized by a p-type gallium nitride (GaN) structure, and the second type light-guiding layer 24 is realized by a p-type aluminum indium gallium nitride (AlInGaN) structure. The second type light-guiding layer 24 and the second type semiconductor layer 23 contacted and disposed below the second type light-guiding layer 24 have the same polarity. Due to the characteristics of the selected material, the second type light-guiding layer 24 can be directly formed on the second type semiconductor layer 23 by way of epitaxial growth. In addition, the light-emitting layer 22 can be realized by a multi-quantum well (MQW) layer for increasing the luminous efficiency when the current flows through the PN junction. Also, due to the characteristics of the selected material, the refractive index of the second type light-guiding layer 24 including AlInGaN is smaller than the refractive index of the second type semiconductor layer 23 including GaN.

Referring to FIG. 2 (b). Partial of the first type semiconductor layer 21, the light-emitting layer 22, the second type semiconductor layer 23 and the second type light-guiding layer 24 is removed and the configuration is illustrated in the diagram. That is, partial stacking of the first semiconductor stacking layer 201 is removed. In the present embodiment, in the step of removing, photolithography technology is adapted. The first semiconductor stacking layer 201 consisting of the first type semiconductor layer 21, the light-emitting layer 22, the second type semiconductor layer 23 and the second type light-guiding layer 24 stacked to each other is patterned, and the stacking layer 201 is etched, so that the pattern of the mask or photoresist used in photolithography technology is transferred to the stacking layer 201. In the present embodiment, the etching thickness of the first type semiconductor layer 21 is determined according to the needs of the manufacturing process and is controlled by adjusting the etching time.

The protrusion formed after the etching process becomes a second semiconductor stacking layer 202. The first type semiconductor layer 21, the light-emitting layer 22, the second type semiconductor layer 23 and the second type light-guiding layer 24 are stacked to each other to form the second semiconductor stacking layer 202, or the remained portion of the first semiconductor stacking layer 201 after the etching process forms the second semiconductor stacking layer 202. Therefore, the light-emitting area containing the light-emitting layer 22 is the second semiconductor stacking layer 202, and the exposed surface of first type semiconductor layer 21 after the etching process is a non-light-emitting area in which a cathode electrode can be disposed subsequently. The cathode electrode contacts the first type (n-type) semiconductor layer 21 for conducting current.

Referring to FIG. 2 (c). A transparent conductive layer 25 is formed on the surface of the second type light-guiding layer 24 of the second semiconductor stacking layer 202. In the present embodiment, the transparent conductive layer 25 is used as a conductivity and current spreading layer like the prior art. With an aim to reducing total reflection inside the LED structure and guiding the generated light to the outside, the transparent conductive layer 25 can be consisting of transparent indium tin oxide (ITO), an oxide containing indium and/or tin and/or zinc structure, or indium oxide (InO), tin oxide (SnO or SnO₂), zinc oxide (ZnO), indium zinc oxide (IZO) or a combination thereof, so that the refractive index of the transparent conductive layer 25 formed by the above material is smaller than that of the second type light-guiding layer 24 formed by aluminum indium gallium nitride (AlInGaN).

Therefore, the refractive index of the second type light-guiding layer 24 is between the refractive indexes of the transparent conductive layer 25 and the second type semiconductor layer 23. Like the design concept of the prior art, the present invention also reduces the total reflection inside the LED structure and guides the light generated inside the LED structure to the outside.

Referring to FIG. 2 (d). An anode electrode 261 is formed on partial surface of the transparent conductive layer 25, and a cathode electrode 262 is formed on the remaining surface of the first type semiconductor layer 21 not covered by the light-emitting layer 22. When current is introduced to the anode electrode 261, current is scattered by the transparent conductive layer 25, conducted downward through the second type light-guiding layer 24, and then is conducted to the outside through the cathode electrode 262, so that the light-emitting layer 22 at the PN junction emits a light.

Therefore, the configuration illustrated in FIG. 2 (d) is an LED structure 200 manufactured by the manufacturing method of an LED structure according to an exemplary embodiment of the present invention. As indicated in the diagram, the LED structure 200 includes a semiconductor substrate 20, a first type semiconductor layer 21, a light-emitting layer 22, a second type semiconductor layer 23, a second type light-guiding layer 24, a transparent conductive layer 25, an anode electrode 261 and a cathode electrode 262. The first type semiconductor layer 21 is formed on the semiconductor substrate 20. The light-emitting layer 22 is formed on partial surface of the first type semiconductor layer 21. The second type semiconductor layer 23 corresponds to a top surface of the light-emitting layer 22 and is formed on the light-emitting layer 22. The second type light-guiding layer 24 corresponds to a top surface of the second type semiconductor layer 23 and is formed on the second type semiconductor layer 23. The transparent conductive layer 25 corresponds to a top surface of the second type light-guiding layer 24 and is formed on the second type light-guiding layer 24. The anode electrode 261 is formed on the transparent conductive layer 25. The cathode electrode 262 is formed on the remaining surface of the first type semiconductor layer 21 not covered by the light-emitting layer 22.

Based on the exemplary embodiment disclosed above, the present invention may make modifications to achieve similar characteristics and features. For example, the LED structure may further include a buffer layer which consists of silicon nitride (Si₃N₄) or silicon oxide (SiO₂) and is disposed between the semiconductor substrate 20 and the first type semiconductor layer 21. The buffer layer is conducive to the quality of the overall epitaxial structure.

According to the design concept of the present invention, aluminum indium gallium nitride (AlInGaN) with lower refractive index is used in the gallium nitride (GaN) structure of the LED for reducing total reflection and increasing luminous efficiency of the overall structure. However, the reverse bias (VFD) is increased as a consequence of the use of aluminum indium gallium nitride in the GAN structure. Therefore, in other implementations, the thickness of the second type light-guiding layer 24 formed by aluminum indium gallium nitride is reduced and the doping concentration at the polarities of the second type light-guiding layer 24 is increased for reducing the reverse bias.

To summarize, the LED structure of the present invention consists of a stacking layer in which the refractive indexes of the layers of the stacking layer can be match with each other (that is, the refractive index of the second type light-guiding layer 24 is between the refractive indexes of the transparent conductive layer 25 and the second type semiconductor layer 23), so that the total reflection inside the structure is effectively reduced and the light generated inside the structure is guided to the outside. Furthermore, due to the material characteristics, the stacking layer may be directly formed by the way of epitaxial growth so as to reduce the time and cost required in the manufacturing process. In the LED structure of the present invention, the scope of the second type light-guiding layer 24, the transparent conductive layer 25 corresponds to a top surface or an upper surface of the second type semiconductor layer 23, the second type light-guiding layer 24, and the anode electrode 261 is only formed on the transparent conductive layer 25, so that current is scattered in the transparent conductive layer 25 and luminous efficiency is increased. Therefore, the present invention can effectively resolve the problems encountered in the prior art and achieve design goals.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light emitting diode (LED) structure, comprising:
a semiconductor substrate;
a first type semiconductor layer formed on the semiconductor substrate;
a light-emitting layer formed on partial surface of the first type semiconductor layer;
a second type semiconductor layer corresponding to the top surface of the light-emitting layer and formed on the light-emitting layer;
a second type light-guiding layer corresponding to the top surface of the second type semiconductor layer and formed on the second type semiconductor layer, wherein the second type light-guiding layer and the second type semiconductor layer have the same polarity; and
a transparent conductive layer corresponding to the top surface of the second type light-guiding layer and formed on the second type light-guiding layer;
wherein, the refractive index of the second type light-guiding layer is between the refractive indexes of the transparent conductive layer and the second type semiconductor layer.

2. The LED structure according to claim 1, wherein the second type light-guiding layer is a p-type aluminum indium gallium nitride (AlInGaN) structure.

3. The LED structure according to claim 2, wherein the second type light-guiding layer is formed by epitaxial process.

4. The LED structure according to claim 1, wherein the first type semiconductor layer is an n-type gallium nitride (GaN) structure, and the second type semiconductor layer is a p-type gallium nitride (GaN) structure.

5. The LED structure according to claim 1, wherein the light-emitting layer is a multi-quantum well (MQW) structure.

6. The LED structure according to claim 1, wherein the material of the transparent conductive layer is an oxide including indium and/or tin and/or zinc.

7. The LED structure according to claim 6, wherein the material of the transparent conductive layer is indium oxide, tin oxide, zinc oxide, indium tin oxide (ITO), indium zinc oxide (IZO) or a combination thereof.

8. The LED structure according to claim 1, further comprising an anode electrode and a cathode electrode, wherein the anode electrode is formed on the transparent conductive layer, and the cathode electrode is formed on the remaining surface of the first type semiconductor layer not covered by the light-emitting layer.

9. The LED structure according to claim 1, further comprising a buffer layer which consists of silicon nitride or silicon oxide and is disposed between the semiconductor substrate and the first type semiconductor layer.

10. A manufacturing method of an LED structure, wherein the method comprises steps of:
providing a semiconductor substrate;
forming a first semiconductor stacking layer on the semiconductor substrate, wherein the first semiconductor stacking layer consists of a first type semiconductor layer, a light-emitting layer, a second type semiconductor layer and a second type light-guiding layer formed in sequence;
patterning the first semiconductor stacking layer to remove partial of the first type semiconductor layer, the light-emitting layer, the second type semiconductor layer and the second type light-guiding layer, wherein a second semiconductor stacking layer consisting of the first type semiconductor layer, the light-emitting layer, the second type semiconductor layer and the second type light-guiding layer is defined in a light-emitting area, and an exposed surface of the first type semiconductor layer is remained in a non-light-emitting area; and
forming a transparent conductive layer on a surface of the second type light-guiding layer of the second semiconductor stacking layer;
wherein the refractive index of the second type light-guiding layer is between the refractive indexes of the second type semiconductor layer and the transparent conductive layer.

11. The manufacturing method of an LED structure according to claim 10, wherein the method comprises steps of:
forming an anode electrode on partial surface of the transparent conductive layer; and
forming a cathode electrode on the remaining surface of the first type semiconductor layer not covered by the light-emitting layer.

12. The manufacturing method of an LED structure according to claim 10, wherein the second type light-guiding layer is formed by epitaxial process and the second type light-guiding layer is a p-type aluminum indium gallium nitride (AlInGaN) structure.

13. The manufacturing method of an LED structure according to claim 10, wherein the first type semiconductor layer is an n-type gallium nitride (GaN) structure, and the second type semiconductor layer is a p-type gallium nitride (GaN) structure.

14. The manufacturing method of an LED structure according to claim 10, wherein the light-emitting layer is a multi-quantum well (MQW) structure.

15. The manufacturing method of an LED structure according to claim 10, wherein the material of the transparent conductive layer is an oxide including indium and/or tin and/or zinc.

16. The manufacturing method of an LED structure according to claim 15, wherein the material of the transparent conductive layer is indium oxide, tin oxide, zinc oxide, ITO, IZO or a combination thereof.

17. The manufacturing method of an LED structure according to claim 10, wherein the LED structure further comprises a buffer layer which consists of silicon nitride or silicon oxide and is disposed between the semiconductor substrate and the first type semiconductor layer.
